(19) United States
(12) Patent Application Publication
(10) Pub. No.: US 2026/0079205 A1
(43) Pub. Date: Mar. 19, 2026

(54) DEBUG SYSTEM AND METHOD FOR OPERATING A DEBUG SYSTEM

(71) Applicant: PUFsecurity CORPORATION, ZHUBEI CITY (TW)

(72) Inventors: CHING-WEN HSU, HSINCHU COUNTY (TW); CHIA-CHO WU, HSINCHU COUNTY (TW)

(21) Appl. No.: 19/329,075

(22) Filed: Sep. 15, 2025

Related U.S. Application Data
(60) Provisional application No. 63/696,388, filed on Sep. 19, 2024.

(51) Int. Cl. G01R 31/3185; G01R 31/317

(52) U.S. Cl. CPC G01R 31/318588; G01R 31/31705; G01R 31/318572

(57) ABSTRACT

The present application discloses a debug system. The debug system includes a DTM, a first DM, a second DM, and a module selector. The first DM is coupled to a first processing core, and the second DM is coupled to a second processing core. The module selector is coupled to the DTM, the first DM, and the second DM. When a selection data register of the DTM is written with a first value, the DTM controls the module selector to select a first path coupled between the DTM and the first DM so as to access the first processing core through the first path. When the selection data register is written with a second value, the DTM controls the module selector to select a second path coupled between the DTM and the second DM so as to access the second processing core through the second path.

### CROSS REFERENCE

This application claims the benefit of prior-filed U.S. provisional application No. 63/696,388, filed on Sep. 19, 2024, which is incorporated by reference in its entirety.

### TECHNICAL FIELD

The present disclosure relates to a debug system, and more particularly, to a debug system capable of controlling multiple debug module with one debug transport module.

### DISCUSSION OF THE BACKGROUND

Joint Test Action Group (JTAG) standard (IEEE 1149.1) is developed for verifying designs and testing printed circuit boards after manufacture. The JTAG-compliant IC may use the Test Access Port (TAP) as an interface to access JTAG functions. Specifically, the TAP controller includes a finite state machine (FSM) that controls the behavior and data flow of the JTAG system. The TAP controller typically adopts five pins: a TCK (Test Clock) pin for synchronization, a TMS (Test Mode Select) pin for navigating its 16-state FSM, a TDI (Test Data In) pin for serial data input, a TDO (Test Data Out) pin for serial data output, and an optional TRST (Test Reset) pin for providing a direct reset. By precisely controlling the TMS signal synchronized to TCK, the TAP controller can direct the JTAG logic through various modes, enabling functions like capturing, shifting, and updating data in internal registers, thereby facilitating boundary scan testing, in-system programming, and embedded system debugging.

JTAG further offers a multi-TAP system for testing and debugging multiple devices. In this setup, several JTAG-compliant devices can be connected in a manner of daisy-chain, allowing a single external JTAG probe to access all devices. Specifically, the TCK pins of all devices are connected in parallel to receive a same clock signal from the JTAG probe. This ensures that all TAP controllers in the chain are synchronized to the same clock signal. Similarly, the TMS pins of all devices are connected in parallel to receive a same mode select signal from the JTAG probe, and the TRST pins of all devices are connected in parallel to receive a same reset signal from the JTAG probe, so the external probe may simultaneously control the state transitions of all TAP controllers in the chain.

In addition, the TDI pin of the first device in the chain is connected to the TDI signal from the JTAG probe. For subsequent devices, the TDO pin of the preceding device is connected to the TDI pin of the current device, thereby creating a single serial data path through all devices. Lastly, the TDO pin of the last device in the chain is connected to the TDO input of the JTAG probe, which allows the external probe to receive the serial data output from the entire JTAG chain.

The fifth generation of Reduced Instruction Set Computing architecture (RISC-V) is also compliant with the JTAG scheme to enable external debugging. Specifically, the debug system of RISC-V may include a debug transport module (DTM) and a debug module (DM). The DTM contains a TAP controller and thus can leverage the JTAG TAP to communicate with the external debugger. The DM is controlled by the DTM, and is responsible for interacting directly with the RISC-V core(s) and providing the actual debug functionalities. Conventionally, the RISC-V debug system only allows one DTM to control one DM, and thus multiple DTMs may be required by a debugging scheme for multiple processors in a same hardware platform, which demands extra gate count of the hardware platform and requires complicated controls. Therefore, how to design the RISC-V debug system in a more efficient way has become an issue to be solved.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a debug system. The debug system includes a debug transport module (DTM), a first debug module (DM), a second DM, and a module selector. The DTM receives commands from a debugger for performing debug operations upon a plurality of processing cores of a hardware platform. The first DM is coupled to at least one first processing core of the hardware platform, and the second DM is coupled to at least one second processing core of the hardware platform. The module selector is coupled to the DTM, the first DM, and the second DM, and the module selector selects at least from a first path coupled between the DTM and the first DM and a second path coupled between the DTM and the second DM. The DTM includes a selection data register coupled to a control terminal of the module selector through a pin of the DTM. When the selection data register is written with a first value, the DTM controls the module selector to select the first path so as to access the at least one first processing core through the first path and the first DM. When the selection data register is written with a second value different from the first value, the DTM controls the module selector to select the second path so as to access the at least one second processing core through the second path and the second DM.

Another aspect of the present disclosure provides a method for operating a debug system to perform debug operations upon a plurality of processing cores of a hardware platform. The debug system includes a DTM, a first DM, a second DM, and a module selector. The first DM is coupled to the at least one first processing core of the hardware platform, and the second DM is coupled to at least one second processing core of the hardware platform. The module selector is coupled to the DTM, the first DM and the second DM. The method includes: when a selection data register of the DTM is written with a first value, the DTM controlling the module selector to select a first path coupled between the DTM and the first DM, the DTM accessing the at least one first processing core through the first path and the first DM after the first path is selected, when the selection data register is written with a second value different from the first value, the DTM controlling the module selector to select a second path coupled between the DTM and the second DM, and the DTM accessing the at least one second processing core through the second path and the second DM after the second path is selected.

### BRIEF DESCRIPTION OF THE PLOTTINGS

A more complete understanding of the present disclosure may be derived by referring to the detailed description and claims when considered in connection with the Figures, where like reference numbers refer to similar elements throughout the Figures.

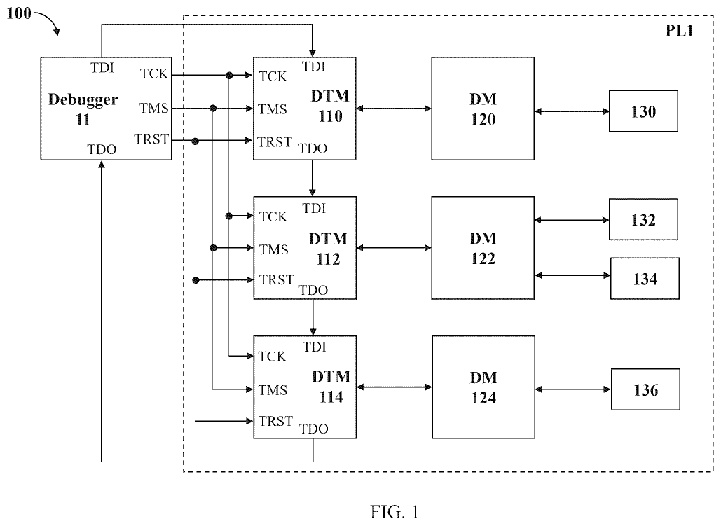

FIG. 1 shows a debug system of a multi-core hardware platform according to one comparative embodiment of the present disclosure.

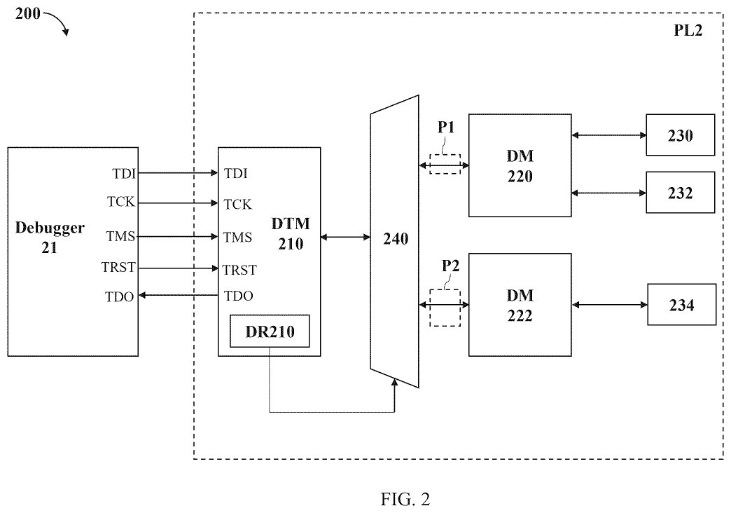

FIG. 2 shows a debug system according to one embodiment of the present disclosure,

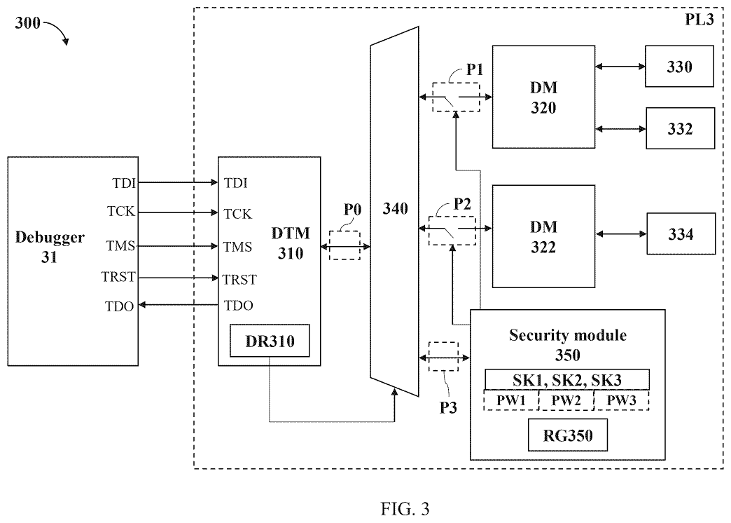

FIG. 3 shows a debug system according to another embodiment of the present disclosure.

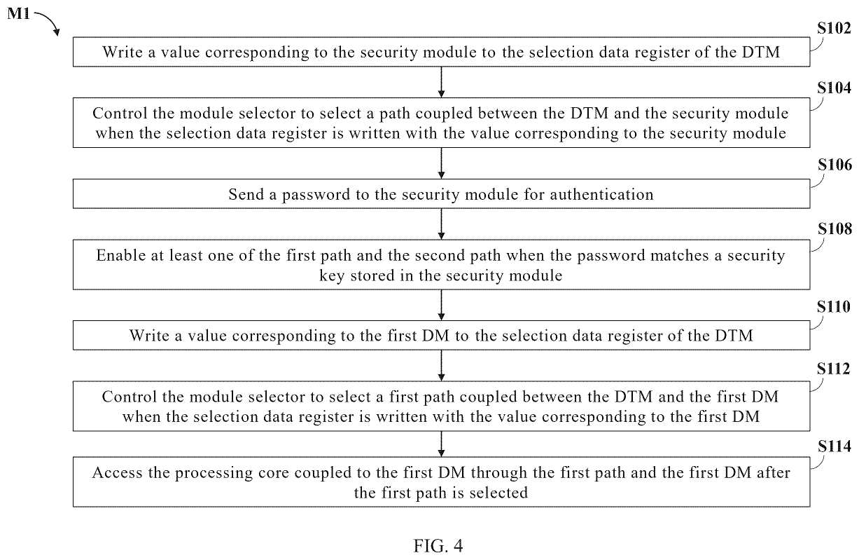

FIG. 4 shows a flowchart of a method for operating the debug system in FIG. 3 to perform debug operations upon processing cores of the hardware platform according to one embodiment of the present disclosure.

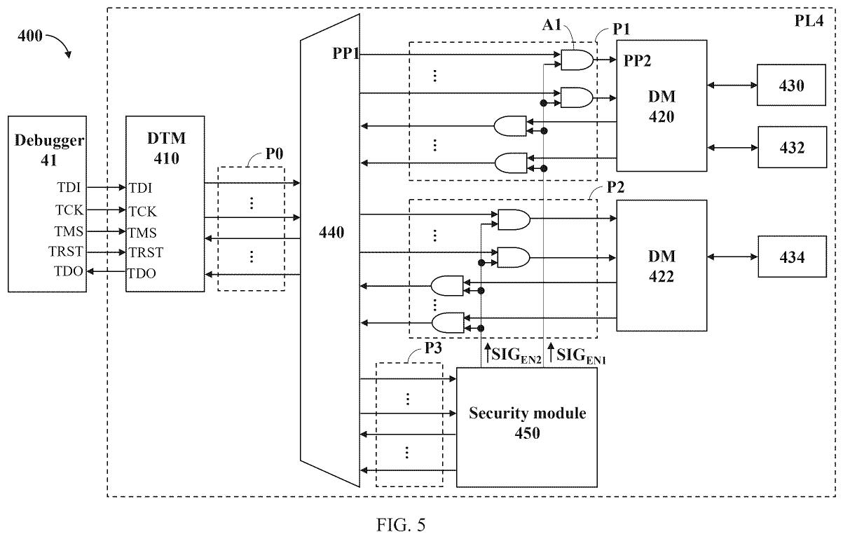

FIG. 5 shows a debug system according to another embodiment of the present disclosure.

### DETAILED DESCRIPTION

FIG. 1 shows a debug system 100 of a multi-core hardware platform according to one comparative embodiment of the present disclosure. The debug system 100 includes debug transport modules (DTMs) 110, 112, and 114, and debug modules (DMs) 120, 122, and 124. The DTMs 110, 112, and 114 and the DMs 120, 122, and 124 are disposed in a hardware platform PL1 having a plurality of processing cores 130, 132, 134, and 136. In some embodiments, the hardware platform PL1 can be a RISC-V platform or a RISC-V based system on chip (SoC). The DTMs 110, 112, and 114 may receive commands from a debugger 11 external to the hardware platform PL1 for performing debug operations upon the multiple processing cores 130, 132, 134, and 136 in the hardware platform PL1.

In the embodiment shown in FIG. 1, the DTMs 110, 112, and 114 are coupled to the debugger 11 through JTAG pins. Specifically, the TCK pins of the DTMs 110, 112, and 114 are coupled to the TCK pin of the hardware platform PL1, the TMS pins of the DTMs 110, 112, and 114 are coupled to the TMS pin of the hardware platform PL1, and the TRST pins of the DTMs 110, 112, and 114 are coupled to the TRST pin of the hardware platform PL1. In addition, the DTMs 110, 112, and 114 are coupled as a daisy-chain. That is, the TDI pin of the DTM 110 is coupled to the TDI pin of the hardware platform PL1, the TDI pin of the DTM 112 is coupled to the TDO pin of the DTM 110, the TDI pin of the DTM 114 is coupled to the TDO pin of the DTM 112, and the TDO pin of the DTM 114 is coupled to the TDO pin of the hardware platform PL1, so that a single serial data path through all DTMs 110, 112, and 114 can be created.

Furthermore, each of the DMs 120, 122, and 124 is coupled to a corresponding DTM of the DTMs 110, 112, and 114. For example, the DM 120 is coupled to the DTM 110, the DM 122 is coupled to the DTM 112, and the DM 124 is coupled to the DTM 114. In addition, each hart (i.e., hardware thread, or a processing core) of the hardware platform PL1 that has its own program counter and register state should be controlled by one DM. In some cases, the hart may be referred as a processing core.

In the debug system 100, each of the DMs 120, 122, and 124 may be coupled to one or more processing core. For example, the DM 120 may be coupled to a processing core 130, the DM 122 may be coupled to processing cores 132 and 134, and the DM 124 may be coupled to a processing core 136. In such case, the debugger 11 needs to access the processing core 130 for performing debugging operations upon the processing core 130 through the DTM 110 and the DM 120, and access the processing core 132 or 134 for performing debugging operations upon the processing core 132 or 134 through the DTM 112 and the DM 122, and so on.

In other words, the debug system 100 requires multiple DTMs 110, 112, and 114 to access the processing cores 130, 132, 134, 136 that are coupled to different DMs 120, 122, and 124. Such configuration may result in suboptimal hardware efficiency, as the inclusion of multiple DTMs 110, 112, and 114 increases the required gate count (circuit area) of the hardware platform PL1, thereby potentially elevating manufacturing costs and complexity. Furthermore, the serial signal path of the chained DTMs 110, 112, and 114 may also lead to increased complexity in the debugging operations.

FIG. 2 shows a debug system 200 according to one embodiment of the present disclosure. The debug system 200 is different from the debug system 100 in that the debug system 200 allows one DTM 210 to connect with multiple DMs 220 and 222 with aids of a module selector 240.

Specifically, the debug system 200 includes the DTM 210, the debug DMs 220 and 222, and the module selector 240. In the present embodiment, the DTM 210, the DMs 220 and 222, and the module selector 240 are disposed in the hardware platform PL2 along with processing cores 230, 232, and 234. The DTM 210 may receive commands from a debugger 21 external to the hardware platform PL2 through TAP pins defined by JTAG for performing debug operations upon the processing cores 230, 232 and 234.

In the present embodiment, each of the DMs 220 and 222 may be coupled to at least one processing core. For example, the DM 220 is coupled to the processing cores 230 and 232, and the DM 222 is coupled to the processing core 234. The module selector 240 is coupled to the DTM 210, and the DMs 220 and 222. The module selector 240 can be, for example but not limited to, a multiplexer, and can select from a path P1 coupled between the DTM 210 and the DM 220 and a path P2 coupled between the DTM 210 and the DM 222, thereby allowing the DTM 210 to access the targeted processing core through the corresponding DM.

According to the specification provided by JTAG for DTM in RISC-V, the DTM 210 may include a plurality of data registers, some of which can be used for specific purposes, while some of which are not explicitly defined and are reserved for other applications. In the present embodiment, the DTM 210 can use a reserved register as the selection data register DR210, for example, but not limited to, the data register having an address of 0x12. In such case, the debugger 21 may write different values to the selection data register DR210 of the DTM 210 for selecting the desired one of the paths P1 and P2 so as to control the corresponding DM. For example, when the selection data register DR210 is written with a first value (e.g., “01”), the DTM 210 may control the module selector 240 to select the path P1 so as to access the processing core 230 or 232 through the path P1 and the DM 220. Also, when the selection data register DR210 is written with a second value (e.g., “10”) different from the first value, the DTM 210 may control the module selector 240 to select the path P2 so as to access the processing core 234 through the path P2 and the DM 222.

In other words, when the debugger 21 needs to perform debugging operations upon the processing core 230 or 232 coupled to the DM 220, the debugger 21 may write the first value to the selection data register DR210 of the DTM 210 so that the DTM 210 can control the module selector 240 to select the path P1 connecting to the DM 220. Once the path P1 is selected and the module selector 240 electrically connects to the DM 220 through the path P1, the debugger 21 may enable the debug module interface (DMI) access of the DTM 210, thereby allowing the DTM 210 to control the DM 220 through the module selector 240. In such case, the module selector 240 can pass the instruction and data received from the DTM 210 to the corresponding DM 220 without passing the instruction or data received from the DTM 210 to the corresponding DM 222. Consequently, the debugger 21 can perform debugging operations upon the processing core 230 or 232 specifically by the DTM 210.

Similarly, when the debugger 21 needs to perform debugging operations upon the processing core 234 coupled to the DM 222, the debugger 21 may write the second value to the selection data register DR210 of the DTM 210 so that the DTM 210 can control the module selector 240 to select the path P2 connecting to the DM 222. Subsequently, the module selector 240 electrically connects to the DM 222 through the path P2, the debugger 21 may enable the DMI access of the DTM 210, thereby allowing the DTM 210 to control the DM 222 through the module selector 240. Consequently, the debugger 21 can perform debugging operations upon the processing core 234 specifically by the DTM 210.

In some embodiments, the selection data register DR210 may be coupled to a control terminal of the module selector 240 through a pin of the DTM 210. In such case, the module selector 240 may determines to select the path P1 or the path P2 according to the value stored in the selection data register DR210 directly.

With the aids of the module selector 240, the DTM 210 can control multiple DMs 220 and 222, and thus, the circuit area required for multiple DTMs as the debug system 100 can be saved. Furthermore, since the debugger 21 can access different processing cores 230, 232 and 234 with one DTM, the delay caused by the chained DTMs in the debug system 100 can be avoided, and the code for performing the debugging operations can also be simplified. As a result, compared to the debug system 100, the debug system 200 can have better hardware efficiency and higher performance.

FIG. 3 shows a debug system 300 according to another embodiment of the present disclosure. The debug system 300 is different from the debug system 200 in that the debug system 300 further includes a security module 350 disposed in the hardware platform PL3 and coupled to the module selector 340. The security module 350 is for authenticating the access of the paths P1 and P2 from the DTM 310 to the DMs 320 and 322.

In the embodiment shown in FIG. 3, before the DTM 310 control the module selector 340 to select the desired path for accessing the targeted processing core, the debugger 31 may have to access the security module 350 for authentication, and the paths P1 and P2 may only be enabled after the authentication succeeds. Specifically, the paths P1 and P2 are disabled by default before the security module 350 enables them. In such case, before utilizing the path P1 or P2 to access the targeted processing core, the debugger 31 may write a third value (e.g., “11”) to the selection data register DR310 of the DTM 310 so that the DTM 310 can control the module selector 340 to select a path P3 coupled between the DTM 310 and the security module 350 first. After the selection data register DR310 is written with the third value, the path P3 is selected, and the module selector 340 electrically connects to the security module 350 through the path P3, and the debugger 31 may further transmit a password PW1 to the security module 350. The security module 350 may store at least one security key, which may, for example but not limited to, be generated by a physically unclonable function (PUF) unit, and if the password PW1 matches the security key SK1 stored in the security module 350, then at least one corresponding path of the paths P1 and P2 can be enabled. As a result, the security module 350 is able to provide a protection scheme before allowing the debugger 31 to access the processing cores 330, 332, and 334.

In some embodiments, the security module 350 may determines that the password PW1 matches the security key SK1 when they have the same value. In such case, the security key SK1 may be provided to the authenticated users in advance, and the user who does not have the security key SK1 would not be able to enable the paths P1 and P2 for accessing the processing cores 330, 332, and 334. However, the present disclosure is not limited thereto. In some embodiments, the security module 350 may determine whether the password PW1 matches the security key SK1 according to other encryption algorithms. Furthermore, in some embodiments, the paths P1 and P2 may be protected by different security keys. That is, while the password PW1 may be utilized to enable the path P1, another password PW2 may be required to enable the path P2. That is, if the debugger 31 needs to access the processing core 334, then the debugger 31 may further control the DTM 310 to send a password PW2 to the security module 350, and if the security module 350 determined that the password PW2 matches another security key SK2 stored in the security module 350, then the security module 350 may further enable the path P2.

Furthermore, in some embodiments, a password PW3 may be adopted to enable both the paths P1 and P2. For example, the debugger 31 may control the DTM 310 to send a password PW3 to the security module 350, and if the security module 350 determined that the password PW3 matches a security key SK3 stored in the security module 350, then the security module 350 may enable both the paths P1 and P2.

FIG. 4 shows a flowchart of a method M1 for operating the debug system 300 to perform debug operations upon processing cores 330, 332, and 334 of the hardware platform PL3 according to one embodiment of the present disclosure. The method M1 includes steps S102, S104, S106, S108, S110, S112, and S114. According to the method M1, when the debugger 31 needs to access the processing core 330 for debugging, the debugger 31 may write a value corresponding to the security module 350 (e.g., the third value “11”) to the selection data register DR310 of the DTM 310 in step S102. As the selection data register DR310 is written with the third value corresponding to the security module 350, the DTM 310 can control the module selector 340 to select the path P3 coupled between the DTM 310 and the security module 350 in step S104.

In step S106, the debugger 31 may send the password PW1 to the security module 350 for authentication, and if the password PW1 matches the security key SK1 stored in the security module 350, the security module 350 can enable the path P1 in step S108.

In some embodiments, after sending the password PW1, the debugger 31 may further control the DTM 310 to read a status register RG350 of the security module 350 so as to check if the path P1 has been enabled correctly or not. Specifically, the status register RG350 can store a status value for indicating at least one of a status of the path P1 and a status of the path P2. For example, the status value “00” may indicate that both paths P1 and P2 are disabled, the status value “01” may indicate that the path P1 is enabled and the path P2 is disabled, the status value “10” may indicate that the path P1 is disabled and the path P2 is enabled, and the status value “11” may indicate that both the paths P1 and P2 are enabled.

In some embodiments, to read the status value stored in the status register RG350, the debugger 31 may control the DTM 310 to enter the “first shift IR” state for selecting the selection data register DR310 (e.g., with the address of 0x12) of the DTM 310, and enters the “first shift DR” state (later than the “first shift IR” state) to write the selection data register DR310 with the third value for controlling the module selector 340 to select the path P3 that connects to the security module 350. Specifically, the debugger 31 may transmit the address and the data (e.g., the third value) to the DTM 310 one bit at a time through the TDI pin. For example, the debugger 31 may command the DTM 310 to enter the “first shift IR” state. When the DTM 310 is in the “first shift IR” state, the DTM 310 can receive the address of the selection data register DR310 through the TDI pin from the debugger 31 one bit at a time, and store the address of the selection data register DR310 into the instruction register (IR). Then, the debugger 31 may command the DTM 310 to enter the “first shift DR” state. When the DTM 310 is in the “first shift DR” state, the DTM 310 can receive the data (e.g., the third value) through the TDI pin from the debugger one bit at a time, and store the third value into the data register DR310.

Subsequently, the debugger 31 may control the DTM 310 to enter the “second shift IR” state (later than the “first shift DR” state) to select another data register (e.g., with the address of 0x11 as defined by JTAG) of the DTM 310 for accessing the DMI, and further control the DTM 310 to enter the “second shift DR” state (later than the “second shift IR” state) to write the address of the status register RG350 of the security module 350 to the data register with the address of 0x11. Finally, the debugger 31 can further control the DTM 310 in the “third shift DR” state (later than the “second shift DR” state) to control the security module 350 to output the status value stored in the status register RG350 (i.e., read operation) so the status value stored in the status register RG350 can be read through the path P3, the module selector 340 to the TDO pin one bit at a time accordingly.

After confirming that the path P1 has been enabled, the debugger 31 can further write a value (e.g., the first value “01”) corresponding to the DM 320 to the selection data register DR310 of the DTM 310 in step S110. In some embodiments, step S110 can be achieved by having the DTM 310 enter the “shift IR” state to select the data register DR310 and enter the “shift DR” state to write the first value. Accordingly, the DTM 310 can control the module selector 340 to select the path P1 in step S112 when the selection data register DR310 is written with the first value. As the path P1 is selected, the debugger 31 may access the processing core 330 through the DTM 310 and the DM 320 in step S114.

In FIG. 3, the paths P1, P2, and P3 can be enabled or disabled by adopting switches, however, the present disclosure is not limited thereto. In some embodiments, some other control schemes may be adopted to enable or disable the paths P1, P2, and P3. Furthermore, in FIG. 3, the path P1 between the module selector 340 and the DM 320, the path P2 coupled between the module selector 340 and the DM 322, the path P3 coupled between the module selector 340 and the security module 350, and the path P0 coupled between the DTM 310 and the module selector 340 are all represented by one single line respectively for brevity. However, in some embodiments, each of the paths P0, P1, P2 and P3 may include a plurality of transmission lines.

FIG. 5 shows a debug system 400 according to another embodiment of the present disclosure. The debug system 400 includes a debugger 41, the DTM 410, the debug DMs 420 and 422, the module selector 440, and the security module 450, wherein the DTM 410, the DMs 420 and 422, the module selector 440, and the security module 450 are disposed in the hardware platform PL4 along with processing cores 430, 432, and 434.

In addition, FIG. 5 further shows the transmission lines of the path P0 coupled between the DTM 410 and the module selector 440, the path P1 coupled between the module selector 440 and the DM 420, the path P2 coupled between the module selector 440 and the DM 422, and the path P3 coupled between the module selector 440 and the security module 450. In the present embodiment, the communication between the DTM 410 and the DMs 420, 422, and the communication between the DTM 410 and the security module 450 may be based on the advanced peripheral bus (APB), and thus, the paths P0, P1, P2, and P3 may include transmission lines for transmitting signals that required by the APB. For example, the transmission lines in each of the paths P0, P1, P2, and P3 may include a plurality of peripheral read data lines, a peripheral ready line, and a peripheral slave error line that are used to transmit corresponding signals from the DTM 410 to the DMs 420, 422 or the security module 450, and may include a peripheral protection control line, a peripheral select line, a peripheral enable line, a peripheral write line, a plurality of peripheral address lines, and a plurality of peripheral write data lines that are used to transmit corresponding signals from the DMs 420, 422 or the security module 450 to the DTM 410.

In the present embodiment, the debug system 400 may include a plurality of AND gates, and each of the transmission lines of the path P1 can be enabled or disabled by an enable signal generated by the security module 350 by utilizing an AND gate. For example, the AND gate A1 has a first input terminal coupled to a pin PP1 of the module selector 440, a second input terminal coupled to the security module 450 for receiving an enable signal SIG_{EN1}, and an output terminal coupled to a pin PP2 of the DM 420. In such case, the security module 450 may disable the connection between the pin PP1 and the pin PP2 by keeping the enable signal SIG_{EN1} at a logic low level. In such case, the signal transmitted from the pin PP1 will be muted by the AND gate A1.

Also, the security module 450 may enable the connection between the pin PP1 and the pin PP2 by having the enable signal SIG_{EN1} at a logic high level so that the signal transmitted from the pin PP1 can pass the AND gate A1 and can be received by the pin PP2 accordingly. The same scheme can be adopted to the other transmission lines of the path P1, and thus, the path P1 can be enabled or disabled by the same enable signal SIG_{EN1} generated by the security module 450. Similarly, the transmission lines of the path P2 can be enabled or disabled by an enable signal SIG_{EN2} generated by the security module 450. However, the present disclosure is not limited thereto. In some other embodiments, the paths P1 and P2 may be controlled by using switches controlled by the security module 450 or by using other suitable control schemes.

In summary, the debug system and the method for operating the debug system to perform debug operations provided by the embodiments of the present disclosure allow to access multiple DMs with one DTM, and thus may achieve better hardware efficiency and higher performance. Furthermore, the debug system and the method for operating the debug system to perform debug operations can further integrate a security module to manage the access of the DMs, and thus, the information security of the processing cores in the platform can be safeguarded.

What is claimed is:

1. A debug system comprising:
a debug transport module (DTM) configured to receive commands from a debugger for performing debug operations upon a plurality of processing cores of a hardware platform; and
a first debug module (DM) coupled to at least one first processing core of the hardware platform;
a second DM coupled to at least one second processing core of the hardware platform; and
a module selector coupled to the DTM, the first DM, and the second DM, and configured to select at least from a first path coupled between the DTM and the first DM and a second path coupled between the DTM and the second DM;
wherein the DTM comprises a selection data register coupled to a control terminal of the module selector through a pin of the DTM, and the DTM is further configured to, when the selection data register is written with a first value, control the module selector to select the first path so as to access the at least one first processing core through the first path and the first DM, and, when the selection data register is written with a second value different from the first value, control the module selector to select the second path so as to access the at least one second processing core through the second path and the second DM.

2. The debug system of claim 1 further comprising:
a security module coupled to the module selector, the first path, and the second path;
wherein the DTM is further configured to
control the module selector to select a third path coupled between the DTM and the security module when the selection data register is written with a third value different from the first value and the second value, and
send a first password to the security module by control of the debugger through the third path for authentication,
wherein the security module is configured to enable at least one of the first path and the second path when the first password matches a first security key stored in the security module.

3. The debug system of claim 2, wherein:
the security module enables the first path when the first password matches the first security key,
the DTM is further configured to send a second password to the security module by the control of the debugger for authentication, and
the security module is further configured to enable the second path when the second password matches a second security key stored in the security module.

4. The debug system of claim 2, wherein:
the security module enables the first path when the first password matches the first security key,
the DTM is further configured to send a third password to the security module by the control of the debugger for authentication, and
the security module is further configured to enable both the first path and the second path when the third password matches a third security key stored in the security module.

5. The debug system of claim 2, wherein the DTM is further configured to read a status register of the security module which stores a status value indicating at least one of a status of the first path and a status of the second path after the DTM sends the first password to the security module.

6. The debug system of claim 2, wherein:
before the security module enables the first path, the first path is disabled by default.

7. The debug system of claim 2, further comprising an AND gate having a first input terminal coupled to a pin of the module selector, a second input terminal coupled to the security module for receiving an enable signal, and an output terminal coupled to a pin of the first DM.

8. The debug system of claim 7, wherein the security module enables the first path by at least generating the enable signal having a logic high level.

9. The debug system of claim 2, wherein:
the DTM is coupled to the debugger through Joint Test Action Group (JTAG) pins;
the DTM receives, in a “first shift IR” state, an address of the selection data register through a TDI pin of the JTAG pins from the debugger, and stores the address of the selection data register into an instruction register;
the DTM receives, in a “first shift DR” state, the third value through the TDI pin from the debugger, and stores the third value to the selection data register, wherein the “first shift DR” state is later than the “first shift IR” state; and
the module selector selects the third path so as to connect the DTM to the security module according to the third value stored in the selection data register.

10. The debug system of claim 9, wherein:
the DTM receives, in a “second shift IR” state, an address of a data register for accessing a debug module interface (DMI) from the debugger, wherein the “second shift IR” state is later than the “first shift DR” state;
the DTM receives, in a “second shift DR” state, an address of a status register of the security module through the TDI pin from the debugger, wherein the “second shift DR” state is later than the “second shift IR” state; and
the DTM further receives, in a “third shift DR” state, a status value stored in the status register from the status register through the third path, and outputs the status value to the debugger through a TDO pin of the JTAG pins one bit at a time, wherein the “third shift DR” state is later than the “second shift DR” state.

11. A method for operating a debug system to perform debug operations upon a plurality of processing cores of a hardware platform, wherein the debug system comprises a debug transport module (DTM), a first debug module (DM), a second DM, and a module selector, the first DM is coupled to at least one first processing core of the hardware platform, the second DM is coupled to at least one second processing core of the hardware platform, the module selector is coupled to the DTM, the first DM and the second DM, and the method comprising
when a selection data register of the DTM is written with a first value, the DTM controlling the module selector to select a first path coupled between the DTM and the first DM;
the DTM accessing the at least one first processing core through the first path and the first DM after the first path is selected;
when the selection data register is written with a second value different from the first value, the DTM controlling the module selector to select a second path coupled between the DTM and the second DM; and
the DTM accessing the at least one second processing core through the second path and the second DM after the second path is selected.

12. The method of claim 11, wherein the debug system further comprises a security module coupled to the module selector, the first path, and the second path, and the method further comprises:
when the selection data register is written with a third value different from the first value and the second value, the DTM controlling the module selector to select a third path coupled between the DTM and the security module;
the DTM sending a first password to the security module through the third path for authentication; and
the security module enabling at least one of the first path and the second path when the first password matches a first security key stored in the security module.

13. The method of claim 12, wherein the security module enables the first path when the first password matches the first security key, and the method further comprises:
the DTM sending a second password to the security module for authentication; and
the security module enabling the second path when the second password matches a second security key stored in the security module.

14. The method of claim 12, wherein the security module enables the first path when the first password matches the first security key, and the method further comprises:
the DTM sending a third password to the security module for authentication; and
the security module enabling both the first path and the second path when the third password matches a third security key stored in the security module.

15. The method of claim 12, further comprising:
the DTM reading a status register of the security module which stores a status value indicating at least one of a status of the first path and a status of the second path after the DTM sends the first password to the security module;
wherein the step of the DTM accessing the at least one first processing core through the first path and the first DM after the first path is selected is performed after the DTM confirms the first path is enabled according to the status value.

16. The method of claim 12, wherein:
before the security module enables the first path, the first path is disabled by default.

17. The method of claim 12, wherein the DTM is coupled to a debugger through Joint Test Action Group (JTAG) pins, and the method further comprises:
when in a “first shift IR” state, the DTM receiving an address of the selection data register through a TDI pin of the JTAG pins from the debugger, and storing the address of the selection data register into an instruction register;
in a “first shift DR” state, the DTM receiving the third value through the TDI pin from the debugger, and storing the third value to the selection data register, wherein the “first shift DR” state is later than the “first shift IR” state; and
the module selector selecting the third path so as to connect the DTM to the security module according to the third value stored in the selection data register.

18. The method of claim 17, wherein the method further comprises:
the DTM receiving, in a “second shift IR” state, an address of a data register for accessing a debug module interface (DMI) from the debugger, wherein the “second shift IR” state is later than the “first shift DR” state;
the DTM receiving, in a “second shift DR” state, an address of a status register of the security module through the TDI pin from the debugger, wherein the “second shift DR” state is later than the “second shift IR” state; and
the DTM further receiving, in a “third shift DR” state, a status value stored in the status register from the status register through the third path, and outputting the status value to the debugger through a TDO pin of the JTAG pins to the debugger one bit at a time, wherein the “third shift DR” state is later than the “second shift DR” state.
